(19) United States
(12) Patent Application Publication
(10) Pub. No.: US 2026/0004853 A1
(43) Pub. Date: Jan. 1, 2026

(54) CONFIGURABLE LOW VOLTAGE DETECTION THRESHOLD AT A MEMORY SYSTEM

(71) Applicant: Micron Technology, Inc., Boise, ID (US)

(72) Inventors: Caixia Yang, Boise, ID (US); Deping He, Boise, ID (US)

(21) Appl. No.: 19/224,471

(22) Filed: May 30, 2025

Related U.S. Application Data
(60) Provisional application No. 63/666,005, filed on Jun. 28, 2024.

(51) Int. Cl. G11C 16/22; G06F 3/06

(52) U.S. Cl. CPC G11C 16/225; G06F 3/0611; G06F 3/0673; G06F 3/0679

(57) ABSTRACT

Methods, systems, and devices for configurable low voltage detection threshold at a memory system are described. The described techniques provide for a memory system to adjust a low voltage detection (LVD) threshold according to an interface speed of the memory system. The LVD threshold may be correlated with the interface speed, such that when operating at a relatively high interface speed, the memory system may set the LVD threshold to a relatively high value and when operating at a relatively low interface speed, the memory system may set the LVD threshold to a relatively low value. Additionally, or alternatively, the memory system may be configured to adjust the LVD threshold when changing an interface speed for subsequent operations. For example, the memory system may receive a command indicating a second interface speed and may set the LVD threshold to a second value that is associated with the second speed.

### CROSS REFERENCE

The present Application for Patent claims priority to U.S. Patent Application No. 63/666,005 by Yang et al., entitled “CONFIGURABLE LOW VOLTAGE DETECTION THRESHOLD AT A MEMORY SYSTEM,” filed Jun. 28, 2024, which is assigned to the assignee hereof, and which is expressly incorporated by reference in its entirety herein.

### TECHNICAL FIELD

The following relates to one or more systems for memory, including configurable low voltage detection threshold (LVD) at a memory system.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports configurable low voltage detection (LVD) threshold at a memory system in accordance with examples as disclosed herein.

FIG. 2 shows an example of a system that supports configurable LVD threshold at a memory system in accordance with examples as disclosed herein.

FIG. 3 shows an example of a process that supports configurable LVD threshold at a memory system in accordance with examples as disclosed herein.

FIG. 4 shows a block diagram of a memory system that supports configurable LVD threshold at a memory system in accordance with examples as disclosed herein.

FIG. 5 shows a flowchart illustrating a method or methods that support configurable LVD threshold at a memory system in accordance with examples as disclosed herein.

### DETAILED DESCRIPTION

Memory systems may include or support components configured to transfer and store data to one or more memory arrays. For example, a memory system may include a controller (e.g., a microcontroller) that interfaces with one or more memory devices to transfer data to memory arrays (e.g., NAND memory) of the one or more memory devices. In some cases, to increase a likelihood that the data is correctly written to the memory arrays, the memory system may monitor a voltage supplied to the memory system (e.g., by a power management component) and compare the voltage with a low voltage detection (LVD) threshold. For example, if the memory system identifies that the supply voltage is below the LVD threshold, the memory system may suspend subsequent operations (e.g., data transfer operations, among other examples) for a duration, such as until the supply voltage is greater than or equal to the LVD threshold. Such suspension may improve signal integrity (SI) of data communications between the controller and the memory devices since the data may be more likely to become corrupted or otherwise be written incorrectly at relatively low supply voltages. The LVD threshold may be a static value configured for the memory system (e.g., set during a manufacturing or development stage). However, a static LVD threshold may result in the memory system suspending operations, thereby increasing latency, when data was otherwise not at risk of being corrupted. For example, the memory system may operate at various interface speeds (e.g., open NAND flash interface (ONFI) speeds), and when operating at a relatively low interface speed, the memory system may have a larger window (e.g., more time) to ensure the data satisfies SI constraints. Thus, comparing supply voltage with a static LVD threshold may result in the memory system suspending operations despite being capable of maintaining data integrity.

Techniques described herein provide for a memory system to adjust (e.g., dynamically) an LVD threshold according to an interface speed of the memory system. In some examples, the memory system may operate according to a first speed of an interface (e.g., an ONFI interface) that supports transferring data to one or more memory devices of the memory system and the memory system may set the LVD threshold to a first value that is associated with the first speed. In some examples, the LVD threshold may be correlated with the interface speed, such that when operating at a relatively high interface speed, the memory system may set the LVD threshold to a relatively high value (e.g., a more stringent LVD threshold) and when operating at a relatively low interface speed, the memory system may set the LVD threshold to a relatively low value (e.g., a more relaxed LVD threshold). Additionally, or alternatively, the memory system may be configured to adjust the LVD threshold when changing an interface speed for subsequent operations. For example, the memory system may receive a command (e.g., a hardware command, such as a universal flash storage (UFS) command) indicating a second interface speed. The memory system may set the LVD threshold to a second value that is associated with the second speed, and may determine whether to continue or suspend subsequent operations by comparing supply voltage to the second value of the LVD threshold. In some cases, the speed of the interface between the controller and the memory devices (e.g., the ONFI interface) may be determined according to a speed of a second interface between the controller and a host system (e.g., a UFS gear speed). Such techniques may decrease latency at the memory system, particularly when the memory system is supplied with inconsistent or otherwise unreliable voltages, by avoiding suspension of operations when the memory system is capable of maintaining data integrity.

In addition to applicability in memory systems as described herein, techniques for configurable LVD thresholds may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving the reliability of memory access operations, which may decrease processing or latency times, improve response times, or otherwise improve user experience, among other benefits.

In addition to applicability in memory systems as described herein, techniques for configurable LVD thresholds may be generally implemented to support edge computing applications. Edge computing is a distributed computing paradigm that brings computation and data storage closer to the sources of data than traditional cloud services. As the use of edge computing to provide computing, storage, and networking services at locations that are geographically closer to end users increases, many devices and systems may benefit from improved processing, performance, and storage at edge devices. For example, increasing memory density, capacity, and processing power of edge devices may decrease a reliance on the devices to remote computing or devices, which may otherwise increase latency of operations performed at the devices. Implementing the techniques described herein may support edge computing techniques by improving memory access speeds at edge computing devices and improving response times associated with edge computing devices, among other benefits.

Features of the disclosure are illustrated and described in the context of systems, devices, and circuits. Features of the disclosure are further illustrated and described in the context of a process and flowcharts.

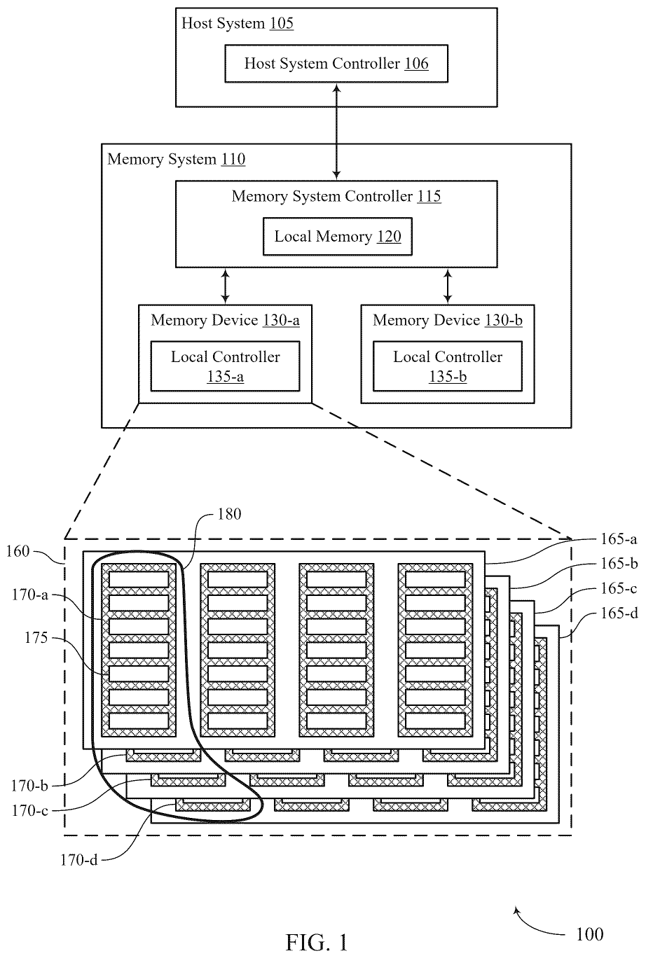

FIG. 1 shows an example of a system 100 that supports configurable LVD threshold at a memory system in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a UFS device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an ONFI, and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

In some examples of the system 100, a memory system controller 115 may interface with one or more memory devices 130 to transfer data to the one or more memory devices 130. To increase a likelihood that the data is correctly written to the memory devices 130, the memory system 110 may monitor a supply voltage (e.g., supplied by a power management component) and compare the supply voltage with an LVD threshold. For example, if the memory system 110 identifies that the supply voltage is below the LVD threshold, the memory system 110 may suspend subsequent operations (e.g., data transfer operations, among other examples) for a duration, such as until the supply voltage is greater than or equal to the LVD threshold. Such suspension may improve the SI of data communications between the memory system controller 115 and the memory devices 130 since the data may be more likely to become corrupted or otherwise be written incorrectly at relatively low supply voltages. The LVD threshold may be a static value configured for the memory system 110 (e.g., set during a manufacturing or development stage). However, a static LVD threshold may result in the memory system 110 suspending operations, thereby resulting in latency, when data was otherwise not at risk of being corrupted. For example, the memory system 110 may operate at various interface speeds (e.g., ONFI speeds), and when operating at a relatively low interface speed, the memory system 110 may have a larger window (e.g., more time) to ensure the data satisfies SI constraints. Thus, comparing supply voltage with a static LVD threshold may result in the memory system 110 suspending operations despite being capable of maintaining data integrity.

Techniques described herein provide for a memory system 110 to adjust (e.g., dynamically) an LVD threshold according to an interface speed of the memory system 110. In some examples, the memory system 110 may operate according to a first speed of an interface (e.g., an ONFI interface) that supports transferring data to one or more memory devices 130 of the memory system 110 and the memory system 110 may set the LVD threshold to a first value that is associated with the first speed. In some examples, the LVD threshold may be correlated with the interface speed, such that when operating at a relatively high interface speed, the memory system 110 may set the LVD threshold to a relatively high value (e.g., a more stringent LVD threshold) and when operating at a relatively low interface speed, the memory system 110 may set the LVD threshold to a relatively low value (e.g., a more relaxed LVD threshold). Additionally, or alternatively, the memory system 110 may be configured to adjust the LVD threshold when changing an interface speed for subsequent operations. For example, the memory system 110 may receive a command (e.g., a hardware command, such as a UFS command) indicating a second interface speed. The memory system 110 may set the LVD threshold to a second value that is associated with the second speed, and may determine whether to continue or suspend subsequent operations by comparing supply voltage to the second value of the LVD threshold. In some cases, the speed of the interface between the memory system controller 115 and the memory devices 130 (e.g., an ONFI interface speed) may be determined according to a speed of a second interface between the memory system controller 115 and a host system 105 (e.g., a UFS gear speed). Such techniques may decrease latency at the memory system 110, particularly when the memory system 110 is supplied with inconsistent or otherwise unreliable voltages, by avoiding suspension of operations when the memory system 110 is capable of maintaining data integrity.

The system 100 may include any quantity of non-transitory computer readable media that support configurable LVD threshold at a memory system. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

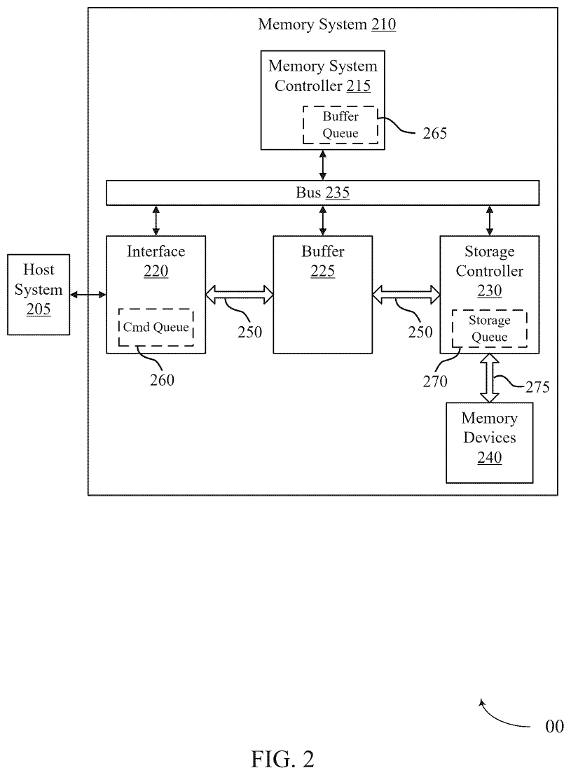

FIG. 2 shows an example of a system 200 that supports configurable LVD threshold at a memory system in accordance with examples as disclosed herein. The system 200 may be an example of a system 100 as described with reference to FIG. 1, or aspects thereof. The system 200 may include a memory system 210 configured to store data received from the host system 205 and to send data to the host system 205, if requested by the host system 205 using access commands (e.g., read commands or write commands). The system 200 may implement aspects of the system 100 as described with reference to FIG. 1. For example, the memory system 210 and the host system 205 may be examples of the memory system 110 and the host system 105, respectively.

The memory system 210 may include one or more memory devices 240 to store data transferred between the memory system 210 and the host system 205 (e.g., in response to receiving access commands from the host system 205). The memory devices 240 may include one or more memory devices as described with reference to FIG. 1. For example, the memory devices 240 may include NAND memory, PCM, self-selecting memory, 3D cross point or other chalcogenide-based memories, FERAM, MRAM, NOR (e.g., NOR flash) memory, STT-MRAM, CBRAM, RRAM, or OxRAM, among other examples.

The memory system 210 may include a storage controller 230 for controlling the passing of data directly to and from the memory devices 240 (e.g., for storing data, for retrieving data, for determining memory locations in which to store data and from which to retrieve data). The storage controller 230 may communicate with memory devices 240 directly or via a bus 275, which may include using a protocol specific to each type of memory device 240 (e.g., ONFI bus). In some cases, a single storage controller 230 may be used to control multiple memory devices 240 of the same or different types. In some cases, the memory system 210 may include multiple storage controllers 230 (e.g., a different storage controller 230 for each type of memory device 240). In some cases, a storage controller 230 may implement aspects of a local controller 135 as described with reference to FIG. 1.

The memory system 210 may include an interface 220 for communication with the host system 205, and a buffer 225 for temporary storage of data being transferred between the host system 205 and the memory devices 240. The interface 220, buffer 225, and storage controller 230 may support translating data between the host system 205 and the memory devices 240 (e.g., as shown by a data path 250), and may be collectively referred to as data path components.

Using the buffer 225 to temporarily store data during transfers may allow data to be buffered while commands are being processed, which may reduce latency between commands and may support arbitrary data sizes associated with commands. This may also allow bursts of commands to be handled, and the buffered data may be stored, or transmitted, or both (e.g., after a burst has stopped). The buffer 225 may include relatively fast memory (e.g., some types of volatile memory, such as SRAM or DRAM), or hardware accelerators, or both to allow fast storage and retrieval of data to and from the buffer 225. The buffer 225 may include data path switching components for bi-directional data transfer between the buffer 225 and other components.

A temporary storage of data within a buffer 225 may refer to the storage of data in the buffer 225 during the execution of access commands. For example, after completion of an access command, the associated data may no longer be maintained in the buffer 225 (e.g., may be overwritten with data for additional access commands). In some examples, the buffer 225 may be a non-cache buffer. For example, data may not be read directly from the buffer 225 by the host system 205. In some examples, read commands may be added to a queue without an operation to match the address to addresses already in the buffer 225 (e.g., without a cache address match or lookup operation).

The memory system 210 also may include a memory system controller 215 for executing the commands received from the host system 205, which may include controlling the data path components for the moving of the data. The memory system controller 215 may be an example of the memory system controller 115 as described with reference to FIG. 1. A bus 235 may be used to communicate between the system components.

In some cases, one or more queues (e.g., a command queue 260, a buffer queue 265, a storage queue 270) may be used to control the processing of access commands and the movement of corresponding data. This may be beneficial, for example, if more than one access command from the host system 205 is processed concurrently by the memory system 210. The command queue 260, buffer queue 265, and storage queue 270 are depicted at the interface 220, memory system controller 215, and storage controller 230, respectively, as examples of a possible implementation. However, queues, if implemented, may be positioned anywhere within the memory system 210.

Data transferred between the host system 205 and the memory devices 240 may be conveyed along a different path in the memory system 210 than non-data information (e.g., commands, status information). For example, the system components in the memory system 210 may communicate with each other using a bus 235, while the data may use the data path 250 through the data path components instead of the bus 235. The memory system controller 215 may control how and if data is transferred between the host system 205 and the memory devices 240 by communicating with the data path components over the bus 235 (e.g., using a protocol specific to the memory system 210).

If a host system 205 transmits access commands to the memory system 210, the commands may be received by the interface 220 (e.g., according to a protocol, such as a UFS protocol or an eMMC protocol). Thus, the interface 220 may be considered a front end of the memory system 210. After receipt of each access command, the interface 220 may communicate the command to the memory system controller 215 (e.g., via the bus 235). In some cases, each command may be added to a command queue 260 by the interface 220 to communicate the command to the memory system controller 215.

The memory system controller 215 may determine that an access command has been received based on the communication from the interface 220. In some cases, the memory system controller 215 may determine the access command has been received by retrieving the command from the command queue 260. The command may be removed from the command queue 260 after it has been retrieved (e.g., by the memory system controller 215). In some cases, the memory system controller 215 may cause the interface 220 (e.g., via the bus 235) to remove the command from the command queue 260.

After a determination that an access command has been received, the memory system controller 215 may execute the access command. For a read command, this may include obtaining data from one or more memory devices 240 and transmitting the data to the host system 205. For a write command, this may include receiving data from the host system 205 and moving the data to one or more memory devices 240. In either case, the memory system controller 215 may use the buffer 225 for, among other things, temporary storage of the data being received from or sent to the host system 205. The buffer 225 may be considered a middle end of the memory system 210. In some cases, buffer address management (e.g., pointers to address locations in the buffer 225) may be performed by hardware (e.g., dedicated circuits) in the interface 220, buffer 225, or storage controller 230.

To process a write command received from the host system 205, the memory system controller 215 may determine if the buffer 225 has sufficient available space to store the data associated with the command. For example, the memory system controller 215 may determine (e.g., via firmware, via controller firmware), an amount of space within the buffer 225 that may be available to store data associated with the write command.

In some cases, a buffer queue 265 may be used to control a flow of commands associated with data stored in the buffer 225, including write commands. The buffer queue 265 may include the access commands associated with data currently stored in the buffer 225. In some cases, the commands in the command queue 260 may be moved to the buffer queue 265 by the memory system controller 215 and may remain in the buffer queue 265 while the associated data is stored in the buffer 225. In some cases, each command in the buffer queue 265 may be associated with an address at the buffer 225. For example, pointers may be maintained that indicate where in the buffer 225 the data associated with each command is stored. Using the buffer queue 265, multiple access commands may be received sequentially from the host system 205 and at least portions of the access commands may be processed concurrently.

If the buffer 225 has sufficient space to store the write data, the memory system controller 215 may cause the interface 220 to transmit an indication of availability to the host system 205 (e.g., a “ready to transfer” indication), which may be performed in accordance with a protocol (e.g., a UFS protocol, an eMMC protocol). As the interface 220 receives the data associated with the write command from the host system 205, the interface 220 may transfer the data to the buffer 225 for temporary storage using the data path 250. In some cases, the interface 220 may obtain (e.g., from the buffer 225, from the buffer queue 265) the location within the buffer 225 to store the data. The interface 220 may indicate to the memory system controller 215 (e.g., via the bus 235) if the data transfer to the buffer 225 has been completed.

After the write data has been stored in the buffer 225 by the interface 220, the data may be transferred out of the buffer 225 and stored in a memory device 240, which may involve operations of the storage controller 230. For example, the memory system controller 215 may cause the storage controller 230 to retrieve the data from the buffer 225 using the data path 250 and transfer the data to a memory device 240. The storage controller 230 may be considered a back end of the memory system 210. The storage controller 230 may indicate to the memory system controller 215 (e.g., via the bus 235) that the data transfer to one or more memory devices 240 has been completed.

In some cases, a storage queue 270 may support a transfer of write data. For example, the memory system controller 215 may push (e.g., via the bus 235) write commands from the buffer queue 265 to the storage queue 270 for processing. The storage queue 270 may include entries for each access command. In some examples, the storage queue 270 may additionally include a buffer pointer (e.g., an address) that may indicate where in the buffer 225 the data associated with the command is stored and a storage pointer (e.g., an address) that may indicate the location in the memory devices 240 associated with the data. In some cases, the storage controller 230 may obtain (e.g., from the buffer 225, from the buffer queue 265, from the storage queue 270) the location within the buffer 225 from which to obtain the data. The storage controller 230 may manage the locations within the memory devices 240 to store the data (e.g., performing wear-leveling, performing garbage collection). The entries may be added to the storage queue 270 (e.g., by the memory system controller 215). The entries may be removed from the storage queue 270 (e.g., by the storage controller 230, by the memory system controller 215) after completion of the transfer of the data.

To process a read command received from the host system 205, the memory system controller 215 may determine if the buffer 225 has sufficient available space to store the data associated with the command. For example, the memory system controller 215 may determine (e.g., via firmware, via controller firmware), an amount of space within the buffer 225 that may be available to store data associated with the read command.

In some cases, the buffer queue 265 may support buffer storage of data associated with read commands in a similar manner as discussed with respect to write commands. For example, if the buffer 225 has sufficient space to store the read data, the memory system controller 215 may cause the storage controller 230 to retrieve the data associated with the read command from a memory device 240 and store the data in the buffer 225 for temporary storage using the data path 250. The storage controller 230 may indicate to the memory system controller 215 (e.g., via the bus 235) when the data transfer to the buffer 225 has been completed.

In some cases, the storage queue 270 may be used to aid with the transfer of read data. For example, the memory system controller 215 may push the read command to the storage queue 270 for processing. In some cases, the storage controller 230 may obtain (e.g., from the buffer 225, from the storage queue 270) the location within one or more memory devices 240 from which to retrieve the data. In some cases, the storage controller 230 may obtain (e.g., from the buffer queue 265) the location within the buffer 225 to store the data. In some cases, the storage controller 230 may obtain (e.g., from the storage queue 270) the location within the buffer 225 to store the data. In some cases, the memory system controller 215 may move the command processed by the storage queue 270 back to the command queue 260.

After the data has been stored in the buffer 225 by the storage controller 230, the data may be transferred from the buffer 225 and sent to the host system 205. For example, the memory system controller 215 may cause the interface 220 to retrieve the data from the buffer 225 using the data path 250 and transmit the data to the host system 205 (e.g., according to a protocol, such as a UFS protocol or an eMMC protocol). For example, the interface 220 may process the command from the command queue 260 and may indicate to the memory system controller 215 (e.g., via the bus 235) that the data transmission to the host system 205 has been completed.

The memory system controller 215 may execute received commands according to an order (e.g., a first-in-first-out order, according to the order of the command queue 260). For each command, the memory system controller 215 may cause data corresponding to the command to be moved into and out of the buffer 225, as discussed herein. As the data is moved into and stored within the buffer 225, the command may remain in the buffer queue 265. A command may be removed from the buffer queue 265 (e.g., by the memory system controller 215) if the processing of the command has been completed (e.g., if data corresponding to the access command has been transferred out of the buffer 225). If a command is removed from the buffer queue 265, the address previously storing the data associated with that command may be available to store data associated with a new command.

In some examples, the memory system controller 215 may be configured for operations associated with one or more memory devices 240. For example, the memory system controller 215 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., LBAs) associated with commands from the host system 205 and physical addresses (e.g., physical block addresses) associated with memory cells within the memory devices 240. For example, the host system 205 may issue commands indicating one or more LBAs and the memory system controller 215 may identify one or more physical block addresses indicated by the LBAs. In some cases, one or more contiguous LBAs may correspond to noncontiguous physical block addresses. In some cases, the storage controller 230 may be configured to perform one or more of the described operations in conjunction with or instead of the memory system controller 215. In some cases, the memory system controller 215 may perform the functions of the storage controller 230 and the storage controller 230 may be omitted.

In some examples of the system 200, a controller of a memory system 210 (e.g., the memory system controller 215 or the storage controller 230) may interface with one or more memory devices 240 to transfer data to the one or more memory devices 240. To increase a likelihood that the data is correctly written to the memory devices 240, the memory system 210 may monitor a supply voltage (e.g., supplied by a power management component) and compare the supply voltage with an LVD threshold. For example, if the memory system 210 identifies that the supply voltage is below the LVD threshold, the memory system 210 may suspend subsequent operations (e.g., data transfer operations, among other examples) for a duration, such as until the supply voltage is greater than or equal to the LVD threshold. Such suspension may improve the SI of data communications between the controller and the memory devices 240 since the data may be more likely to become corrupted or otherwise be written incorrectly at relatively low supply voltages. The LVD threshold may be a static value configured for the memory system 210 (e.g., set during a manufacturing or development stage). However, a static LVD threshold may result in the memory system 210 suspending operations, thereby resulting in latency, when data was otherwise not at risk of being corrupted. For example, the memory system 210 may operate at various interface speeds (e.g., ONFI speeds), and when operating at a relatively low interface speed, the memory system 210 may have a larger window (e.g., more time) to ensure the data satisfies SI constraints. Thus, comparing supply voltage with a static LVD threshold may result in the memory system 210 suspending operations despite being capable of maintaining data integrity.

Techniques described herein provide for a memory system 210 to adjust (e.g., dynamically) an LVD threshold according to an interface speed of the memory system 210. In some examples, the memory system 210 may operate according to a first speed of an interface (e.g., an ONFI interface) that supports transferring data to one or more memory devices 240 of the memory system 210 and the memory system 210 may set the LVD threshold to a first value that is associated with the first speed. In some examples, the LVD threshold may be correlated with the interface speed, such that when operating at a relatively high interface speed, the memory system 210 may set the LVD threshold to a relatively high value (e.g., a more stringent LVD threshold) and when operating at a relatively low interface speed, the memory system 210 may set the LVD threshold to a relatively low value (e.g., a more relaxed LVD threshold). Additionally, or alternatively, the memory system 210 may be configured to adjust the LVD threshold when changing an interface speed for subsequent operations. For example, the memory system 210 may receive a command (e.g., a hardware command, such as a UFS command) indicating a second interface speed. The memory system 210 may set the LVD threshold to a second value that is associated with the second speed, and may determine whether to continue or suspend subsequent operations by comparing supply voltage to the second value of the LVD threshold. In some cases, the speed of the interface between the controller and the memory devices 240 (e.g., an ONFI interface speed) may be determined according to a speed of a second interface (e.g., the interface 220) between the controller and a host system 205 (e.g., a UFS gear speed). Such techniques may decrease latency at the memory system 210, particularly when the memory system 210 is supplied with inconsistent or otherwise unreliable voltages, by avoiding suspension of operations when the memory system 210 is capable of maintaining data integrity.

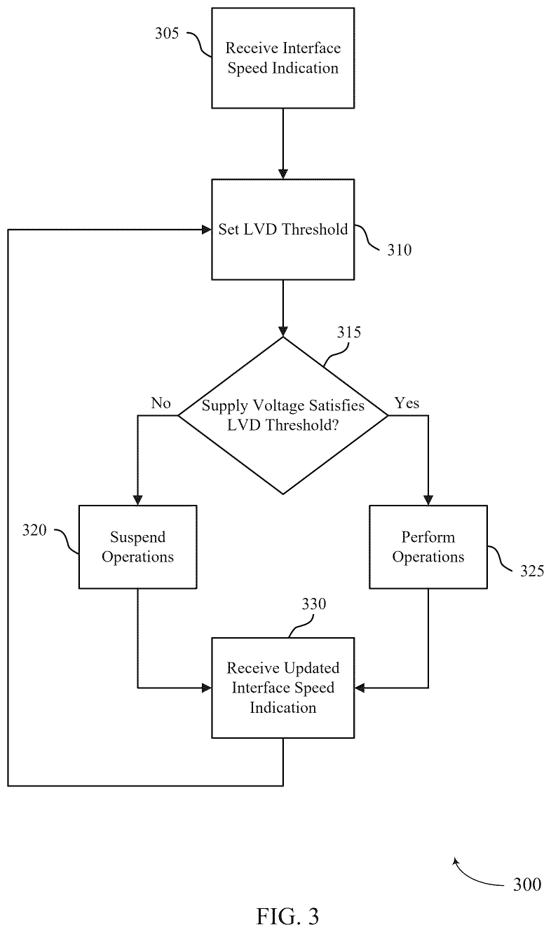

FIG. 3 shows an example of a process 300 that supports configurable LVD threshold at a memory system in accordance with examples as disclosed herein. The process 300 may implement, or be implemented by, one or more aspects of the systems 100 and 200. For example, the process 300 may illustrate examples of operations performed by a memory system, which may be an example of corresponding device described with reference to FIGS. 1 and 2. In some cases, the process 300 may support the memory system dynamically adjusting an LVD threshold according to an interface speed (e.g., an ONFI speed) of the memory system. For example, the interface speed may be associated with an interface between a controller of the memory system and one or more memory devices of the memory system, which may be examples of corresponding devices described with reference to FIGS. 1 and 2.

Aspects of the process 300 may be implemented by one or more controllers, among other components. Additionally, or alternatively, aspects of the process 300 may be implemented as instructions stored in one or more memories (e.g., firmware stored in one or more memories coupled with the memory system). For example, the instructions, when executed by one or more controllers (e.g., a memory system controller 115), may cause the one or more controllers (or a device or a system) to perform the operations of the process 300. Alternative examples of the following may be implemented, where some steps are performed in a different order or not at all. Additionally, some steps may include additional features not mentioned

At 305, an interface speed indication may be received. For example, a controller of the memory system (e.g., a memory system controller 115 or a memory system controller 215) may receive an indication of a first speed for an interface (e.g., an ONFI interface) associated with transferring data between the controller and one or more memory devices of the memory system. In some examples, the first speed for the interface may be indicated in a hardware command received by the memory system. For example, the memory system may receive a UFS command indicating the first speed for the interface. Additionally, or alternatively, the memory system may determine the first speed of the interface based on determining that a speed of a second interface (e.g., a UFS interface) between the controller and a host system is less than a threshold. For example, the memory system may determine a UFS gear speed to support determining the ONFI interface speed. In some cases, the ONFI interface speed and the UFS gear speed may be examples of parameters related to a hardware clock of the memory system.

As an example, when the UFS gear speed is relatively low (e.g., gear 1 (G1)) the memory system may determine to operate according to a relatively low ONFI speed (e.g., an ONFI speed of DDR400 may be sufficient to satisfy a G1 speed). Alternatively, when the UFS gear speed is relatively high (e.g., gear 5 (G5)) the memory system may determine to operate according to a relatively high OFNI speed (e.g., an ONFI speed of DDR1600 up to DDR3600 may satisfy a G5 speed). The memory system may operate according to the first speed for the ONFI to perform one or more operations, such as data transfer operations, among other examples (e.g., memory management operations, access operations, or the like).

At 310, an LVD threshold may be set. For example, the controller of the memory system may set the LVD threshold to a first value. The memory system may maintain the LVD threshold to support detecting voltage supply errors at the memory system and prevent data from being corrupted or otherwise incorrectly written to the memory devices of the memory system. For example, low supply voltages may degrade the SI of data being transferred to the memory devices, and the data may be at risk of corruption when the memory system receives relatively low supply voltages. The memory system may compare the supply voltage with the LVD threshold to determine whether to continue operations or to suspend operations. For example, if the supply voltage is below the LVD threshold, the memory system may determine to suspend operations for a duration (e.g., until the supply voltage is greater than or equal to the LVD threshold) to avoid data loss. Alternatively, if the supply volage is above the LVD threshold, the memory system may determine to continue performing operations (e.g., due to data transfers being safer at sufficient supply voltages).

In some examples, the value of the LVD threshold may be associated with a current ONFI speed of the memory system. For example, when operating at relatively high interface speeds, a window associated with ensuring SI of the data may be relatively small (e.g., at DDR3600, a bit width may be less than 300 ps), and the memory system may set the LVD threshold to a relatively high value to protect the SI of the data. As another example, when operating at relatively low interface speeds, the window associated with ensuring SI of the data may be relatively large (e.g., at DDR400, a bit width may be 2500 ps), and the memory system may set the LVD threshold to a relatively low value to prevent the LVD threshold from being frequently triggered and thereby incurring undue latency (e.g., since deficiencies in supply voltage may be supplemented by a larger SI window).

At 315, whether a supply voltage satisfies the LVD threshold may be determined. For example, the controller of the memory system may compare the supply voltage (e.g., supplied by a power management component of the memory system) with the LVD threshold to determine whether the supply voltage is suitable for performing subsequent operations. In some examples, the memory system may determine that the supply voltage does not satisfy (e.g., is less than) the LVD threshold, and the memory system may proceed to step 320 of the process 300. Alternatively, the memory system may determine that the supply voltage satisfies (e.g., is greater than or equal to) the LVD threshold, and may proceed to step 325 of the process 300.

At 320, operations may be suspended. For example, the controller of the memory system may suspend one or more subsequent operations based on to detecting that the supply voltage does not satisfy the LVD threshold. The memory system may suspend the operations for a duration, which may be associated with a time between detecting the supply voltage below the LVD threshold and detecting that the supply voltage increased to be greater than or equal to the LVD threshold. In some examples, suspending the operations may avoid data loss or corruption associated with transferring data to memory devices at substantially low supply voltages.

At 325, operations may be performed. For example, the controller of the memory system may perform one or more subsequent operations based on to detecting that the supply voltage satisfies the LVD threshold. In some cases, performing the operations may include transferring data to one or more memory devices, where the data transfer may satisfy SI constraints (e.g., associated with avoiding data loss or corruption) due to the supply voltage satisfying the LVD threshold.

At 330, an updated interface speed indication may be received. For example, the controller of the memory system may receive an indication of a second speed of the interface for subsequent operations by the memory system. In some cases, in response to receiving the indication of the second speed, the memory system may return to step 310 of the process 300 and may set the LVD threshold (e.g., dynamically) to a second value that is associated with the second speed. For example, the second value of the LVD threshold may be greater than the first value of the LVD threshold when the second speed of the interface is greater than the first speed of the interface. Similarly, the second value of the LVD threshold may be less than the first value of the LVD threshold when the second speed of the interface is less than the first speed of the interface. The memory system may then continue to perform the steps of the process 300, such as determining whether to suspend or continue operations by comparing the supply voltage with the second value of the LVD threshold.

Such techniques may improve performance of the memory system when transferring data to one or more memory devices, particularly when the memory system experiences frequent voltage fluctuations, frequent interface speed adjustments, or both, by preventing suspension of operations due to low supply voltage when data transfers are otherwise not at risk of becoming corrupted.

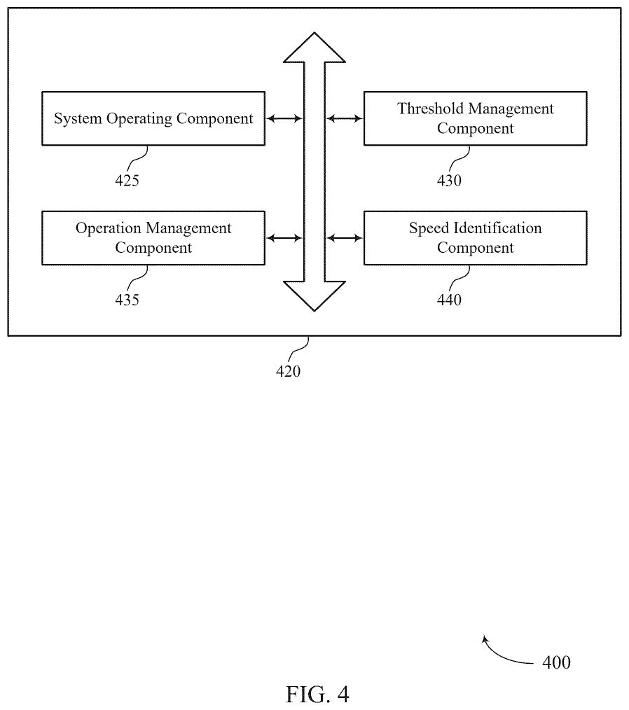

FIG. 4 shows a block diagram 400 of a memory system 420 that supports configurable LVD threshold at a memory system in accordance with examples as disclosed herein. The memory system 420 may be an example of aspects of a memory system as described with reference to FIGS. 1 through 3. The memory system 420, or various components thereof, may be an example of means for performing various aspects of configurable LVD threshold at a memory system as described herein. For example, the memory system 420 may include a system operating component 425, a threshold management component 430, an operation management component 435, a speed identification component 440, or any combination thereof. Each of these components, or components of subcomponents thereof (e.g., one or more processors, one or more memories), may communicate, directly or indirectly, with one another (e.g., via one or more buses).

The system operating component 425 may be configured as or otherwise support a means for operating the memory system in accordance with a first speed of an interface associated with transferring data between a controller of the memory system and one or more memory devices of the memory system. The threshold management component 430 may be configured as or otherwise support a means for setting a threshold to a first value, the threshold associated with detecting voltage supply errors at the memory system, where the first value is in accordance with the first speed. The operation management component 435 may be configured as or otherwise support a means for determining whether to suspend one or more operations in response to comparing a voltage supplied to the memory system with the threshold set to the first value.

In some examples, the speed identification component 440 may be configured as or otherwise support a means for receiving an indication of a second speed of the interface for subsequent operations by the memory system. In some examples, the threshold management component 430 may be configured as or otherwise support a means for setting the threshold to a second value, where the second value is in accordance with the second speed. In some examples, the operation management component 435 may be configured as or otherwise support a means for determining whether to suspend the one or more operations in response to comparing the voltage supplied to the memory system with the threshold set to the second value.

In some examples, the second value is greater than the first value when the second speed is greater than the first speed; and the second value is less than the first value when the second speed is less than the first speed.

In some examples, to support determining whether to suspend the one or more operations, the operation management component 435 may be configured as or otherwise support a means for suspending the one or more operations in response to determining that the voltage supplied to the memory system is less than the threshold set to the first value.

In some examples, to support determining whether to suspend the one or more operations, the system operating component 425 may be configured as or otherwise support a means for performing the one or more operations in response to determining that the voltage supplied to the memory system is greater than the threshold set to the first value.

In some examples, the speed identification component 440 may be configured as or otherwise support a means for receiving a hardware command indicating the first speed, where operating in accordance with the first speed is in response to receiving the hardware command.

In some examples, the hardware command is a UFS command.

In some examples, the threshold is an LVD threshold.

In some examples, the interface is an ONFI.

In some examples, operating in accordance with the first speed of the interface includes determining that a speed of a second interface between the controller and a host system is less than a threshold.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

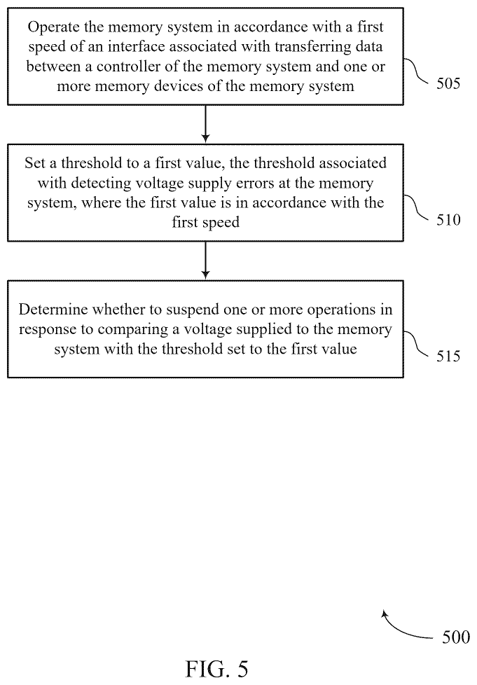

FIG. 5 shows a flowchart illustrating a method 500 that supports configurable LVD threshold at a memory system in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include operating the memory system in accordance with a first speed of an interface associated with transferring data between a controller of the memory system and one or more memory devices of the memory system. In some examples, aspects of the operations of 505 may be performed by a system operating component 425 as described with reference to FIG. 4.

At 510, the method may include setting a threshold to a first value, the threshold associated with detecting voltage supply errors at the memory system, where the first value is in accordance with the first speed. In some examples, aspects of the operations of 510 may be performed by a threshold management component 430 as described with reference to FIG. 4.

At 515, the method may include determining whether to suspend one or more operations in response to comparing a voltage supplied to the memory system with the threshold set to the first value. In some examples, aspects of the operations of 515 may be performed by an operation management component 435 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for operating the memory system in accordance with a first speed of an interface associated with transferring data between a controller of the memory system and one or more memory devices of the memory system; setting a threshold to a first value, the threshold associated with detecting voltage supply errors at the memory system, where the first value is in accordance with the first speed; and determining whether to suspend one or more operations in response to comparing a voltage supplied to the memory system with the threshold set to the first value.

Aspect 2: The method, apparatus, or non-transitory computer-readable medium of aspect 1, further including operations, features, circuitry, logic, means, or instructions, or any combination thereof for receiving an indication of a second speed of the interface for subsequent operations by the memory system; setting the threshold to a second value, where the second value is in accordance with the second speed; and determining whether to suspend the one or more operations in response to comparing the voltage supplied to the memory system with the threshold set to the second value.

Aspect 3: The method, apparatus, or non-transitory computer-readable medium of aspect 2, where the second value is greater than the first value when the second speed is greater than the first speed; and the second value is less than the first value when the second speed is less than the first speed.

Aspect 4: The method, apparatus, or non-transitory computer-readable medium of any of aspects 1 through 3, where determining whether to suspend the one or more operations includes operations, features, circuitry, logic, means, or instructions, or any combination thereof for suspending the one or more operations in response to determining that the voltage supplied to the memory system is less than the threshold set to the first value.

Aspect 5: The method, apparatus, or non-transitory computer-readable medium of any of aspects 1 through 4, where determining whether to suspend the one or more operations includes operations, features, circuitry, logic, means, or instructions, or any combination thereof for performing the one or more operations in response to determining that the voltage supplied to the memory system is greater than the threshold set to the first value.

Aspect 6: The method, apparatus, or non-transitory computer-readable medium of any of aspects 1 through 5, further including operations, features, circuitry, logic, means, or instructions, or any combination thereof for receiving a hardware command indicating the first speed, where operating in accordance with the first speed is in response to receiving the hardware command.

Aspect 7: The method, apparatus, or non-transitory computer-readable medium of aspect 6, where the hardware command is a UFS command.

Aspect 8: The method, apparatus, or non-transitory computer-readable medium of any of aspects 1 through 7, where the threshold is an LVD threshold.

Aspect 9: The method, apparatus, or non-transitory computer-readable medium of any of aspects 1 through 8, where the interface is an ONFI.

Aspect 10: The method, apparatus, or non-transitory computer-readable medium of any of aspects 1 through 9, where operating in accordance with the first speed of the interface includes determining that a speed of a second interface between the controller and a host system is less than a threshold.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
operate the memory system in accordance with a first speed of an interface associated with transferring data between a controller of the memory system and one or more memory devices of the memory system;
set a threshold to a first value, the threshold associated with detecting voltage supply errors at the memory system, wherein the first value is in accordance with the first speed; and
determine whether to suspend one or more operations in response to comparing a voltage supplied to the memory system with the threshold set to the first value.

2. The memory system of claim 1, wherein the processing circuitry is further configured to cause the memory system to:
receive an indication of a second speed of the interface for subsequent operations by the memory system;
set the threshold to a second value, wherein the second value is in accordance with the second speed; and
determine whether to suspend the one or more operations in response to comparing the voltage supplied to the memory system with the threshold set to the second value.

3. The memory system of claim 2, wherein:
the second value is greater than the first value when the second speed is greater than the first speed; and
the second value is less than the first value when the second speed is less than the first speed.

4. The memory system of claim 1, wherein, to determine whether to suspend the one or more operations, the processing circuitry is configured to cause the memory system to:
suspend the one or more operations in response to determining that the voltage supplied to the memory system is less than the threshold set to the first value.

5. The memory system of claim 1, wherein, to determine whether to suspend the one or more operations, the processing circuitry is configured to cause the memory system to:
perform the one or more operations in response to determining that the voltage supplied to the memory system is greater than the threshold set to the first value.

6. The memory system of claim 1, wherein the processing circuitry is further configured to cause the memory system to:
receive a hardware command indicating the first speed, wherein operating in accordance with the first speed is in response to receiving the hardware command.

7. The memory system of claim 6, wherein the hardware command is a universal flash storage command.

8. The memory system of claim 1, wherein the threshold is a low voltage detection threshold.

9. The memory system of claim 1, wherein the interface is an open NAND flash interface (ONFI).

10. The memory system of claim 1, wherein, to operate in accordance with the first speed of the interface, the processing circuitry is configured to cause the memory system to:
determine that a speed of a second interface between the controller and a host system is less than a threshold.

11. A non-transitory computer-readable medium storing code comprising instructions which, when executed by one or more processors of a memory system, cause the memory system to:
operate the memory system in accordance with a first speed of an interface associated with transferring data between a controller of the memory system and one or more memory devices of the memory system;
set a threshold to a first value, the threshold associated with detecting voltage supply errors at the memory system, wherein the first value is in accordance with the first speed; and
determine whether to suspend one or more operations in response to comparing a voltage supplied to the memory system with the threshold set to the first value.

12. The non-transitory computer-readable medium of claim 11, wherein the instructions, when executed by the one or more processors of the memory system, further cause the memory system to:
receive an indication of a second speed of the interface for subsequent operations by the memory system;
set the threshold to a second value, wherein the second value is in accordance with the second speed; and
determine whether to suspend the one or more operations in response to comparing the voltage supplied to the memory system with the threshold set to the second value.

13. The non-transitory computer-readable medium of claim 12, wherein:
the second value is greater than the first value when the second speed is greater than the first speed; and
the second value is less than the first value when the second speed is less than the first speed.

14. The non-transitory computer-readable medium of claim 11, wherein the instructions to determine whether to suspend the one or more operations, when executed by the one or more processors of the memory system, cause the memory system to:
suspend the one or more operations in response to determining that the voltage supplied to the memory system is less than the threshold set to the first value.

15. The non-transitory computer-readable medium of claim 11, wherein the instructions to determine whether to suspend the one or more operations, when executed by the one or more processors of the memory system, cause the memory system to:
perform the one or more operations in response to determining that the voltage supplied to the memory system is greater than the threshold set to the first value.

16. The non-transitory computer-readable medium of claim 11, wherein the instructions, when executed by the one or more processors of the memory system, further cause the memory system to:
receive a hardware command indicating the first speed, wherein operating in accordance with the first speed is in response to receiving the hardware command.

17. The non-transitory computer-readable medium of claim 16, wherein the hardware command is a universal flash storage command.

18. The non-transitory computer-readable medium of claim 11, wherein the threshold is a low voltage detection threshold.

19. The non-transitory computer-readable medium of claim 11, wherein the interface is an open NAND flash interface (ONFI).

20. The non-transitory computer-readable medium of claim 11, wherein the instructions to operate in accordance with the first speed of the interface, when executed by the one or more processors of the memory system, cause the memory system to:
determine that a speed of a second interface between the controller and a host system is less than a threshold.

21. A method by a memory system, comprising:
operating the memory system in accordance with a first speed of an interface associated with transferring data between a controller of the memory system and one or more memory devices of the memory system;
setting a threshold to a first value, the threshold associated with detecting voltage supply errors at the memory system, wherein the first value is in accordance with the first speed; and
determining whether to suspend one or more operations in response to comparing a voltage supplied to the memory system with the threshold set to the first value.

22. The method of claim 21, further comprising:
receiving an indication of a second speed of the interface for subsequent operations by the memory system;
setting the threshold to a second value, wherein the second value is in accordance with the second speed; and
determining whether to suspend the one or more operations in response to comparing the voltage supplied to the memory system with the threshold set to the second value.

23. The method of claim 22, wherein:
the second value is greater than the first value when the second speed is greater than the first speed; and
the second value is less than the first value when the second speed is less than the first speed.

24. The method of claim 21, wherein determining whether to suspend the one or more operations comprises:
suspending the one or more operations in response to determining that the voltage supplied to the memory system is less than the threshold set to the first value.

25. The method of claim 21, wherein determining whether to suspend the one or more operations comprises:
performing the one or more operations in response to determining that the voltage supplied to the memory system is greater than the threshold set to the first value.
